(19) United States
(12) Patent Application Publication
(10) Pub. No.: US 2012/0037065 A1
(43) Pub. Date: Feb. 16, 2012

(54) CRUCIBLE FOR SILICON SUITABLE FOR PRODUCING SEMICONDUCTORS

(75) Inventors: Rolf Wagner, Selb (DE); Florian Arzberger, Thiersheim (DE)

(73) Assignee: H.C. Starck GmbH, Goslar (DE)

(21) Appl. No.: 13/258,458

(22) PCT Filed: Feb. 11, 2010
(86) PCT No.: PCT/EP2010/051695

§ 371 Date: Oct. 17, 2011

(30) Foreign Application Priority Data
Apr. 1, 2009 (DE) 10 2009 015 236.9

(51) Int. Cl. C30B 15/10; C04B 35/65

(52) U.S. Cl. 117/13; 117/208; 264/633

(57) ABSTRACT

A crucible for producing a silicon suitable for producing a semiconductor includes a plurality of components and at least one unclosed joint gap.

### CROSS REFERENCE TO PRIOR APPLICATIONS

This application is a U.S. National Phase application under 35 U.S.C. §371 of International Application No. PCT/EP2010/051695, filed on Feb. 11, 2010 and which claims benefit to German Patent Application No. 10 2009 015 236.9, filed on Apr. 1, 2009. The International Application was published in German on Oct. 7, 2010 as WO 2010/112259 A1 under PCT Article 21(2).

### FIELD

The present invention provides sintered bodies made of inorganic materials, for example, nitride-bonded silicon nitride.

### BACKGROUND

Crucibles, which are sometimes referred to as pots and/or melting pots, made of pure silicon nitride essentially have two possible uses. It can be used in place of graphite kiln furniture for producing kiln furniture made of silicon nitride, which is used in the production of Si₃N₄ components, and it can be used for nonferrous melts, such as, for example, aluminum and silicon melts.

Crucibles and plates made of graphite are currently used in the production of Si₃N₄ components. The kiln atmosphere is to a high degree also responsible for the quality of the sintered product. Since Si₃N₄ tends to react with the carbon of the graphite, the inner walls and the graphite firing plates are preferably coated with expensive boron nitride in order to suppress this reaction. Specific kiln furniture, such as crucibles or plates made of silicon nitride for the production of components made of silicon nitride, are therefore preferred.

In photovoltaics and for pulling silicon single crystals, quartz crucibles are currently used. These crucibles can, however, only be used once.

A solution to this problem would be crucibles made of silicon nitride. However, free-standing crucibles made in one piece have the problem that they can crack during use, since silicon nitride, like many ceramic materials, is sensitive to tensile stress.

The production of free-standing crucibles of the commercially desired size in the basic dimensions of about 70 cm×70 cm up to about 90 cm×90 cm is also difficult since the kilns must be considerably oversized for such bulky green bodies.

WO 2007/148986 and WO 2007/148987 describe free-standing crucibles of silicon nitride and a production method therefor. These publications address the aforementioned problem of the manufacturing difficulty of crucibles being composed of a plurality of interlocking plates and sealed with a specific, low-viscosity paste before the firing, which together produce a free-standing crucible of individual plates after the reaction firing. However, as a result of the considerable stiffness of the crucible corner edges, this type of construction has the risk that the edge region is subjected to tensile stress and that cracks can arise.

### SUMMARY

An aspect of the present invention is to provide crucibles which can be produced cost-effectively, wherein work can be carried out in conventional kilns absent a large dead volume, and wherein a cracking of the crucibles during use can at the same time be avoided. An alternative aspect of the present invention is to provide crucibles for multiple use so as to increase economic efficiency.

In an embodiment, the present invention provides a crucible for producing a silicon suitable for producing a semiconductor which includes a plurality of components and at least one unclosed joint gap.

### BRIEF DESCRIPTION OF THE DRAWINGS

The present invention is described in greater detail below on the basis of embodiments and of the drawings in which:

FIG. 1 shows such first crucible according to the present invention;

FIG. 2 shows a second crucible according to the present invention; and

FIG. 3 shows embodiments joint gaps according to the present invention.

### DETAILED DESCRIPTION

It was hitherto assumed that the crucibles always had to be tightly closed in order to prevent the liquefied silicon from flowing out and thus prevent loss or contamination, and that this had to be effected either via special sealing of the gaps or else by tightly joining together silicon nitride plates.

It has now surprisingly been found that this is not necessary.

Firstly, the crucible need not always close tightly, but rather only when the silicon melt is present, since the gap size of the joint gap only needs to be small enough to prevent the ingress of the powder filling. Secondly, there does not need to be a complete seal since liquid silicon, due to its wetting behavior and its surface tension, behaves differently from other liquids such as, for example, water, and therefore narrow, unclosed joint gaps in the crucible, which at the same time act as expansion joints so as to prevent cracking, do not allow silicon to flow out.

The present invention is therefore based on the idea of joining together a crucible from individual plates in such a way that the joint gaps close only upon the thermal expansion of the material so as to avoid mechanical stresses which can lead to the fracture of the crucible. The present invention is also based on the idea that the joint gap does not have to be completely closed when the molten silicon occurs, but rather it is sufficient if this joint gap is narrow and long enough to ensure that the liquid silicon, due to its wetting behavior and its surface tension, cannot escape. This provides that the plates do not apply pressure to one another due to the individual thermal expansion and thus do not produce undesirable tensile stresses which lead to the cracking or fracture of the crucible or of crucible parts. This provides that the crucibles according to the present invention can be repeatedly reused.

In an embodiment, the present invention provides a crucible for producing silicon suitable for producing semiconductors, wherein the crucible is composed of a plurality of components and has at least one unclosed joint gap. At the maximum application temperature within the range of 1400° C. to 1600° C., the joint gap has a width of generally about 0.05 mm to 0.5 mm, for example, between 0.1 mm to 0.2 mm.

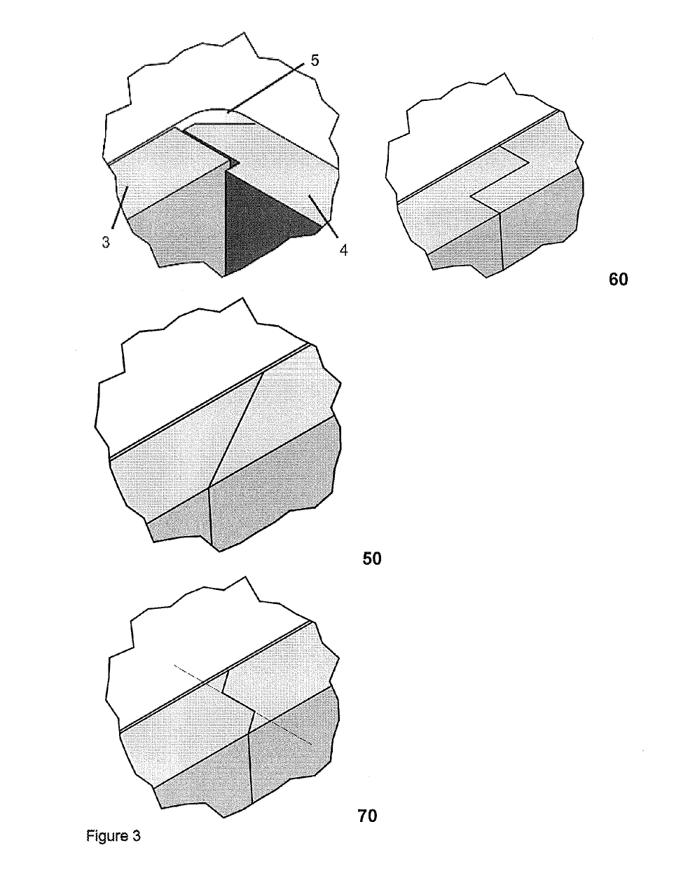

The joint gap can have various forms in plan view, in the simplest case embodied as a butt joint, but also, for example, as a miter cut (50), undercut (60), dovetail or modifications of a dovetail joint (70), as a tongue-and-groove joint or as modifications of a tongue-and-groove joint. Embodiments of these joint gaps are shown in FIG. 3. In crucibles having a small absolute expansion, a joint as a butt joint or right-angled joint locations can be sufficient while in relatively large crucibles, more complex embodiments of the joint gaps can be advantageous. According to an embodiment of the present invention, the components of the crucible are kept in the desired shape by a supporting cage.

In this case, the side walls and/or base parts can have a one-piece or multi-piece embodiment and can also be connected to one another via joint gaps. The multi-piece embodiment of in each case the individual side walls and base parts can be advantageous in relatively large crucibles, for example, in the commercially desired sizes with basic dimensions within the range of about 70 cm×70 cm to about 90 cm×90 cm. The multi-piece configuration of the crucible walls and of the base allows the requisite total expansion to be distributed over a plurality of joint gaps, such that the joint gaps do not become too large at room temperature and ingress of the basic materials, which can be present, for example, as a filling of powder or granulated material, is therefore avoided. The form and width of the joint gaps can be adapted in a simple manner with due regard to the materials used for the crucible and the supporting cage, to the particle sizes occurring in the powder filling and to the size of the crucible.

In an embodiment of the present invention, construction compared to the prior art is simplified in that the crucible or the walls of the crucible need not necessarily contribute to the mechanical stability of the construction, since such mechanical stability can be effected, for example, by a supporting cage.

In an embodiment of the present invention, the supporting cage can, for example, be produced from all materials which do not exhibit an impairment of mechanical stability thereof or any release of volatile impurities at the high temperatures suitable for melting silicon. Due to the different expansion behavior of the components of the crucible and of the supporting cage, if the crucible and the supporting cage are made of different materials, the gap size will be a function of the coefficient of thermal expansion of both materials.

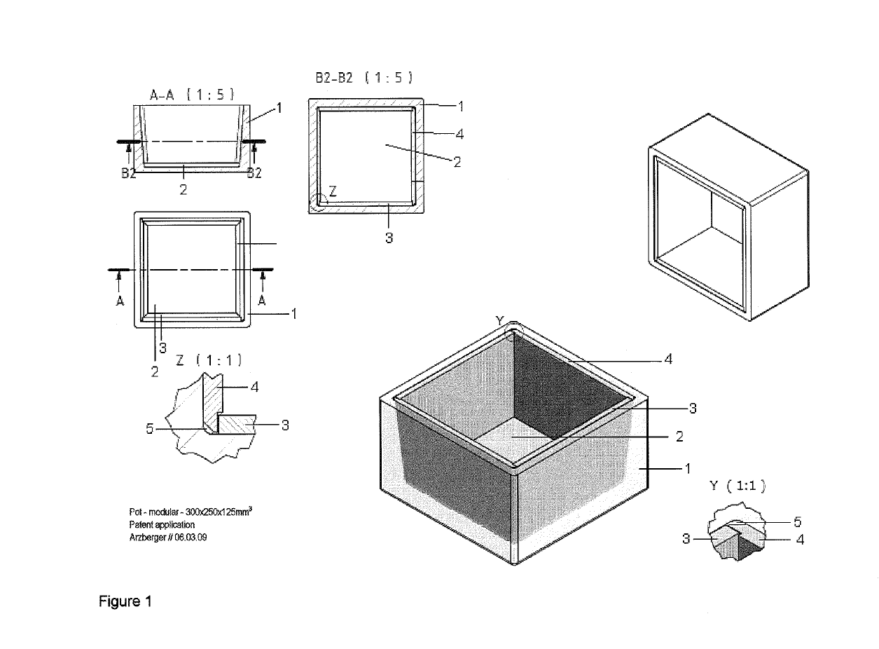

Suitable materials for the supporting cage can, for example, be graphite or molybdenum. The supporting cage can, for example, have both a monolithic and a multi-piece embodiment. In an embodiment of the present invention, the crucible can, for example, be composed of planar elements which are inserted into a graphite crucible. A frame of L-shaped profiles can also be used in order to hold the planar elements. In an embodiment, the present invention provides a crucible for producing silicon suitable for producing semiconductors, consisting of a supporting cage (1), at least one base element (2) and two side walls (3) and two side walls (4) in alternating sequence, wherein at least two sides walls (4) are constituted at least one edge in such a way that they form a positive-locking connection with the side wall (3), wherein all the side walls (3) and (4) sit in an abutting manner on the base element and thus jointly form a cavity (5) and all the base elements and side walls are in contact with the supporting cage and are kept in shape by the latter. FIG. 1 shows such a crucible according to the present invention. In the crucible according to the present invention, the side walls (3) and side walls (4) can also each have the same shape.

In an embodiment, the crucible according to the present invention can also be configured so that at least two side walls (4) have steps at least one edge, the steps overlapping an edge of at least one side wall (3) and forming a positive-locking connection with the edge of the side wall (3).

In an embodiment, the side walls (3) and side walls (4) can be connected to one another via a miter cut.

In an embodiment, the edges of the side walls (3) and/or side walls (4) can be cut off in such a way that a cavity (5) is formed between the corner formed by the side walls (3) and (4) and the corner of the supporting cage (1).

In an embodiment of the crucible according to the present invention, the surfaces of the side walls (3) and (4) can sit in an abutting manner on the base element (2) and can have such an angle to the surface normal so that the wall elements form an isosceles trapezoid, the top and bottom side edges running parallel to one another and the side edges forming congruent angles.

In an embodiment, the side walls (3) and (4) and the base element (2) can be fitted together without using a sealing compound.

In the embodiment of the crucible according to the present invention as depicted in FIG. 1, the two side walls (3) and two side walls (4) are arranged in an alternating sequence if at least two side walls (4) have steps at two opposite edges, said steps overlapping in each case an edge of a side wall (3) and forming a positive-locking connection with the edge of the side wall (3).

In view of the above-described size of the commercially desired crucibles (basic dimensions of about 70 cm×70 cm to about 90 cm×90 cm), it can be appropriate for the base element (2) to be made of a plurality of base parts and/or for the side walls (3) to be made of a plurality of side parts (30).

In an embodiment of a crucible according to the present invention, the side walls (4) can be made of a plurality of side parts (40).

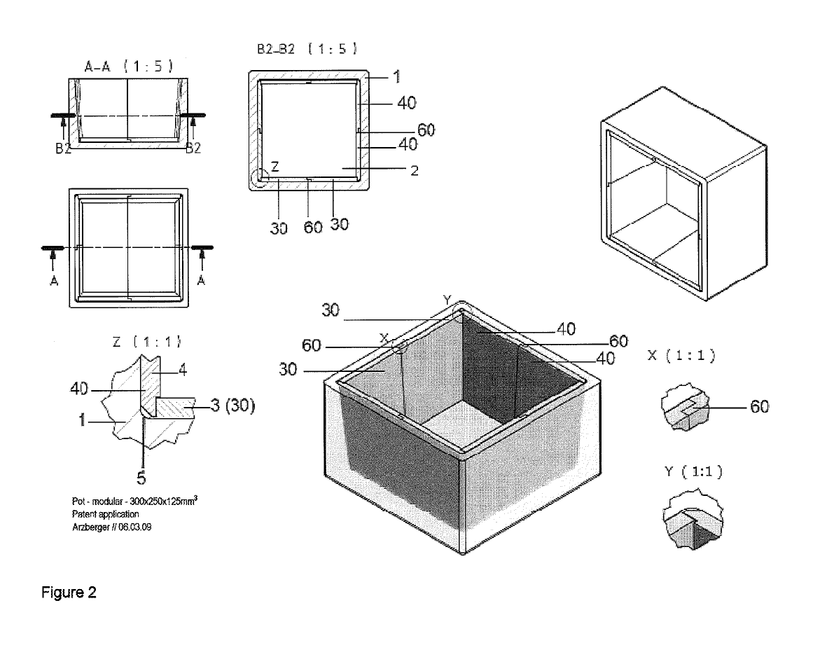

In an embodiment of the crucibles according to the present invention, the base parts (20) and/or side parts (30) and/or side parts (40) of the base element (2) or of the side walls respectively can in each case be connected to one another via a butt joint, a miter cut (50), an undercut (60) or modifications of a dovetail joint (70). Such a crucible is depicted in FIG. 2. The supporting cage can, for example, be a graphite crucible. In a particularly advantageous manner, all the parts can be made of nitride-bonded silicon nitride (NSN).

The present invention also provides a method for producing a crucible for producing silicon suitable for producing semiconductors as described above, said method having the following steps:

mixing silicon nitride powder with silicon powder and if need be organic bonding agents so as to obtain a powder mixture;

forming green bodies from the powder mixture which produce the side walls (3), (4), base elements (2), side parts (30), (40) or base parts (20);

if need be, mechanically processing the green bodies;

heat treating the, if need be mechanically processed, green bodies in a nitrogen atmosphere, the green bodies being transformed into nitrogen-bonded silicon nitride by nitriding the silicon powder.

In an embodiment of the method of the present invention, the powder mixture contains, for example, 20 to 35% by weight of silicon powder, with respect to the inorganic solids content of the powder, 80 to 65% by weight of silicon nitride powder with a grain size distribution of D50<1.0 μm, with respect to the inorganic solids content of the powder, and at least one organic bonding agent in a quantity of 3 to 10% by weight of the organic solids of the powder mixture.

The green bodies can generally be formed by conventional ceramic shaping processes, such as wet pressing, slip casting or advantageously by dry pressing.

In the method for producing the crucible according to the present invention, the side walls (3), (4), base elements (2), side parts (30), (40) or base parts (20) that are obtained can then be arranged in the supporting cage (1) so that the parts produce the crucible.

The present invention also provides a method for producing silicon suitable for producing semiconductors, said method having the steps:

providing a crucible as set forth above;

crystallizing silicon suitable for producing semiconductors and optionally also metallurgical silicon material in the crucible.

In the method for producing silicon suitable for producing semiconductors, the walls of the crucible can be at least partially insulated with graphite or carbon.

The present invention is not limited to embodiments described herein; reference should be had to the appended claims.

What is claimed is:

1-22. (canceled)

23: A crucible for producing a silicon suitable for producing a semiconductor, the crucible comprising a plurality of components and at least one unclosed joint gap.

24: The crucible as recited in claim 23, wherein the crucible further comprises:
a supporting cage;
at least one base element; and
two first side walls and two second side walls arranged in an alternating sequence, wherein at least one respective edge of each of the two second sides walls are provided so as to form a positive-locking connection with the two first side walls, the two first side walls and the two second side walls are arranged in a form-closing manner on the at least one base element so as to form a cavity, and the at least one base element, the two first side walls and the two second side walls are in contact with and are held in position by the supporting cage.

25: The crucible as recited in claim 24, wherein the two first side walls and the two second side walls each have the same shape.

26: The crucible as recited in claim 24, wherein at least one edge of each of the two second side walls comprise steps, the steps being configured so as to grip over an edge of at least one of the two first side walls so as to form a form closure therewith.

27: The crucible as recited in claim 24, wherein the two first side walls and the two second side walls are connected with each another via a miter cut.

28: The crucible as recited in claim 24, wherein edges of at least one of the two first side walls and the two second side walls are cut off so as to form the cavity, the cavity being disposed between a corner formed by a first side wall and a second side wall and a corner of the supporting cage.

29: The crucible as recited in claim 24, wherein surfaces of the two first side walls and the two second side walls, which are configured to sit in an abutting manner on the at least one base element, have an angle to a surface normal so that wall elements form an isosceles trapezoid, a top side edge and a bottom side edge running parallel to one another and side edges forming congruent angles.

30: The crucible as recited in claim 24, wherein the two first side walls, the two second side walls and at least one the base element are fitted together without using a sealing compound.

31: The crucible as recited in claim 24, wherein the two first side walls and the two second side walls are arranged in an alternating sequence, wherein two opposite edges of each of the two second side walls comprise steps, the steps being configured so as to grip over an edge of at least one respective edge the two first side walls so as to form a form closure therewith.

32: The crucible as recited in claim 24, wherein at least one of a) the at least one base element comprises a plurality of base parts, b) the two first side walls comprise a plurality of first side parts, and c) the two second side walls comprise a plurality of second side parts.

33: The crucible as recited in claim 32, wherein at least one of the plurality of base parts, b) the plurality of first side parts, c) the plurality of second side parts, d) the two first side walls, and e) the two second side walls are, respectively, connected to each other via at least one of a) a butt joint, b) a miter cut, c) an undercut, and d) modifications of a dovetail joint.

34: The crucible as recited in claim 32, wherein a) the plurality of base parts, b) the plurality of first side parts, c) the plurality of second side parts, d) the two first side walls, e) the two second side walls are, and f) the at least one base element are each, respectively, made of nitride-bonded silicon nitride (NSN).

35: The crucible as recited in claim 24, wherein the supporting cage is a graphite crucible.

36: The crucible as recited in claim 23, wherein, the at least one unclosed joint gap has a width of less than about 1 mm at a maximum application temperature of from 1400° C. to 1600° C.

37: The crucible as recited in claim 36, wherein the width is from 0.05 mm to 0.2 mm.

38: A method for producing a crucible as recited in claim 33, the method comprising:
mixing a silicon nitride powder with a silicon powder so as to obtain a powder mixture;
forming a green body from the powder mixture so as to produce the plurality of base parts, b) the plurality of first side parts, c) the plurality of second side parts, d) the two first side walls and e) the two second side walls; and
heat treating the green body in a nitrogen atmosphere so as to transform the green body into a nitrogen-bonded silicon nitride by nitriding the silicon powder.

39: The method as recited in claim 38, wherein at least one organic bonding agent is mixed with the silicon nitride powder and the silicon powder so as to obtain the powder mixture, and further comprising:
mechanically processing the green bodies prior to the heat treating.

40: The method as recited in claim 40, wherein the powder mixture contains 20 to 35 wt.-% of the silicon powder, based on an inorganic solids content of the powder mixture, 65 to 80 wt.-% of the silicon nitride powder having a grain size distribution of D50<1.0 μm, based on the inorganic solids content of the powder mixture, and 3 to 10 wt.-% of the at least one organic bonding agent, based on of the organic solids of the powder mixture.

41: The method as recited in claim 38, wherein the forming is preformed by dry pressing.

42: The method as recited in claim 38, wherein at least one of a) the plurality of base parts, b) the plurality of first side parts, c) the plurality of second side parts, d) the two first side walls and e) the two second side walls are arranged in the supporting cage so as to produce the crucible.

43: A method for producing silicon suitable for producing semiconductors, the method comprising:
providing a crucible comprising:
a supporting cage,
at least one base element, and
two first side walls and two second side walls arranged in an alternating sequence, wherein at least one respective edge of each of the two second sides walls are provided so as to form a positive-locking connection with the two first side walls, the two first side walls and the two second side walls are arranged in an form-closing manner on the at least one base element so as to form a cavity, and the at least one base element, the two first side walls and the two second side walls are in contact with and are held in position by the supporting cage; and
crystallizing a silicon suitable for producing semiconductors in the crucible.

44: The method as recited in claim 44, wherein the crystallizing further includes a metallurgical silicon.

45: The method as recited in claim 44, wherein the two first side walls and the two second side walls are at least partially insulated with at least one of a graphite and a carbon.
